(19) United States
(12) Patent Application Publication
(10) Pub. No.: US 2014/0291795 A1
(43) Pub. Date: Oct. 2, 2014

(54) CABLE CONNECTING STRUCTURE AND CABLE CONNECTING METHOD

(71) Applicant: Kabushiki Kaisha Toshiba, Tokyo (JP)

(72) Inventor: Takashi Mori, Fussa-shi (JP)

(73) Assignee: Kabushiki Kaisha Toshiba, Tokyo (JP)

(21) Appl. No.: 14/187,040

(22) Filed: Feb. 21, 2014

Related U.S. Application Data
(63) Continuation of application No. PCT/JP2013/001739, filed on Mar. 14, 2013.

(30) Foreign Application Priority Data
Nov. 30, 2012 (JP) 2012-262130

(51) Int. Cl. H01L 23/00; H01L 27/146

(52) U.S. Cl. CPC H01L 24/09; H01L 24/85; H01L 27/14632; H01L 27/14687
USPC 257/459; 438/612

(57) ABSTRACT

The embodiments provide a cable connecting structure and a cable connecting method that can downsize a head unit.

The embodiment of a cable connecting structure has a semiconductor chip and a cable. A semiconductor chip has a plurality of imaging elements on a front surface thereof and a connection pad formed on a side surface thereof. A cable is connected to the connection pad.

### CROSS-REFERENCE TO RELATED APPLICATION

This application is a continuation of prior International Application No. PCT/JP2013/001739 filed on Mar. 14, 2013, which is based upon and claims the benefit of priority from Japanese Patent Application No. 2012-262130 filed on Nov. 30, 2012; the entire contents of all of which are incorporated herein by reference.

### FIELD

Embodiments described herein relate generally to a cable connecting structure and a cable connecting method.

### BACKGROUND

Imaging apparatuses include a head separation type imaging apparatus in which a head part having an imaging element (for example, a Charge Coupled Device (CCD) image sensor or a Complementary Metal Oxide Semiconductor (CMOS) image sensor) is separated from a main body part which processes an image signal transmitted from the head part. In the head separation type imaging apparatus, the head part and the main body part are connected via a camera cable. Conventionally, the image sensor and the cable are connected by Tape Amounted Bonding (TAB). In recent years, the head part of the head separation type imaging apparatus is required to be further downsized.

### BRIEF DESCRIPTION OF THE DRAWINGS

FIG. 1 is a configuration diagram of an imaging apparatus according to an embodiment.

FIG. 2A is structural views of an image sensor according to the embodiment. FIG. 2B is structural views of an image sensor according to the embodiment.

FIG. 3A is structural views of a head part according to the embodiment. FIG. 3B is structural views of a head part according to the embodiment.

FIG. 4A is explanatory views of a method of connecting a cable to the image sensor according to the embodiment. FIG. 4B is explanatory views of a method of connecting a cable to the image sensor according to the embodiment.

FIG. 5A is explanatory views of the method of connecting the cable to the image sensor according to the embodiment. FIG. 5B is explanatory views of the method of connecting the cable to the image sensor according to the embodiment.

FIG. 6A is structural views of an image sensor according to a modification example 1 of the embodiment. FIG. 6B is structural views of an image sensor according to a modification example 1 of the embodiment.

FIG. 7A is structural views of a head part according to the modification example 1 of the embodiment. FIG. 7B is structural views of a head part according to the modification example 1 of the embodiment.

FIG. 8A is structural views of an image sensor according to a modification example 2 of the embodiment. FIG. 8B is structural views of an image sensor according to a modification example 2 of the embodiment.

FIG. 9A is structural views of a head part according to the modification example 2 of the embodiment. FIG. 9B is structural views of a head part according to the modification example 2 of the embodiment.

FIG. 10A is structural views of image sensors according to other embodiments. FIG. 10B is structural views of image sensors according to other embodiments. FIG. 10C is structural views of image sensors according to other embodiments.

### DETAILED DESCRIPTION

The problem is to provide a cable connecting structure and a cable connecting method that can downsize a head unit.

A cable connecting structure according to an embodiment includes a semiconductor chip and a cable. The semiconductor has a plurality of imaging elements on a front surface thereof and a connection pad formed on a side surface thereof. The cable is connected to the connection pad.

The embodiment provides a cable connecting structure and a cable connecting method that can downsize a head unit.

Hereinafter, an embodiment will be described referring to the drawings.

### Embodiment

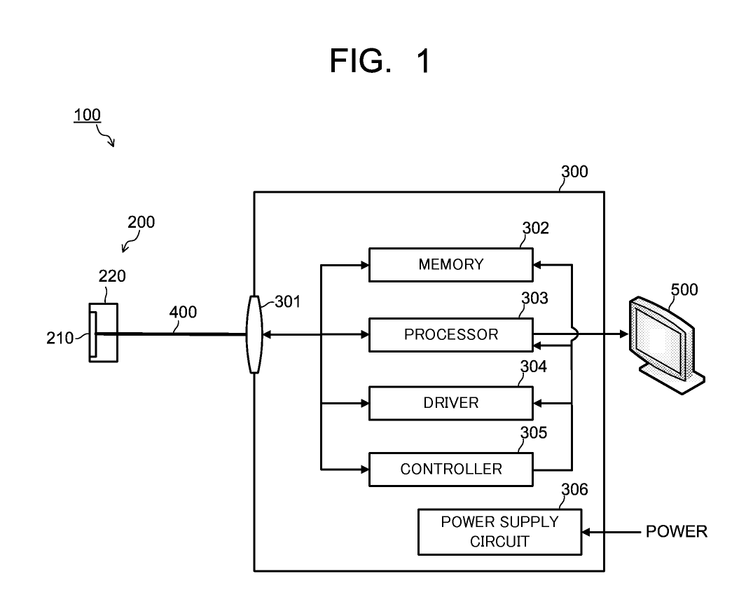

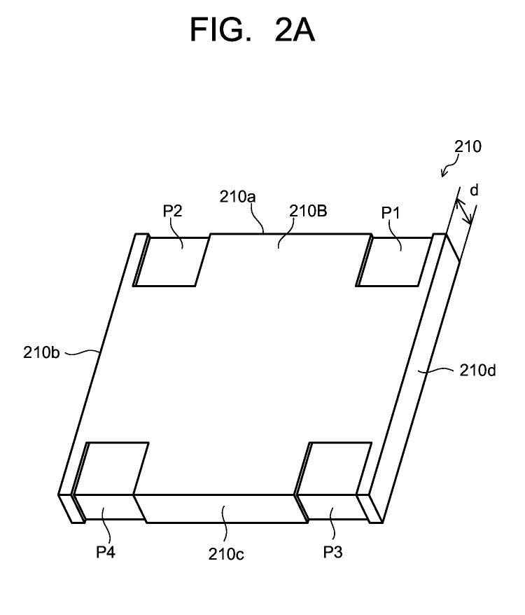

FIG. 1 is a configuration diagram of an imaging apparatus 100 according to the embodiment (hereinafter, referred to as the imaging apparatus 100). The imaging apparatus 100, which is, for example, an endoscope apparatus, includes a head part 200, a Camera Control Unit (CCU) 300 (hereinafter, referred to as a main body part 300), and a camera cable 400 which connects the head part 200 and the main body part 300.

The head part 200 includes an image sensor 210 and a casing 220 which supports and accommodates the image sensor 210. The image sensor 210 is a solid state imaging element such as, for example, a Complementary Metal Oxide Semiconductor (CMOS) image sensor or a Charge Coupled Device (CCD) image sensor. In this embodiment, an imaging element, a drive circuit and so on are formed on the image sensor 210. Further, the cable 400 is directly connected to the image sensor 200.

The main body part 300 includes an IF circuit 301, a memory 302, a processor 303, a driver 304, a controller 305, and a power supply circuit 306.

The IF circuit 301 is an interface for transmitting and receiving control signals and data to/from the head part 200.

The memory 302 is a non-volatile memory. The memory 302 is, for example, a serial EEPROM (Electrically Erasable Programmable Read-Only Memory). In the memory 302, setting data (operation mode) and correction data for the head part 200 are stored.

The processor 303 is a processor for image processing. The processor 303 performs various kinds of correction (for example, noise correction, white balancing, gamma correction and so on) on an image signal transmitted thereto from the head part 200. The processor 303 outputs the corrected image signal to an external display apparatus 500 (for example, a Cathode Ray Tube (CRT) or a liquid crystal monitor).

The driver 304 is a drive circuit for the image sensor 210. The driver 304 changes the driving mode and the frame rate of the image sensor 210 on the basis of control from the controller 305. The driver 304 further outputs pulse signals (for example, pulse signals for vertical synchronization and horizontal synchronization (transfer pulse signal, reset gate pulse signal)) to the image sensor 210.

The controller 305 reads the correction data and the setting data out of the memory 302. The controller 305 controls the processor 303 and the driver 304 on the basis of the read correction data and setting data.

The power supply circuit 306 is connected to an external power supply. The power supply circuit 306 converts the power from the external power supply to a predetermined voltage and supplies the predetermined voltage to the circuits constituting the main body part 300 (the IF circuit 301, the memory 302, the processor 303, the driver 304, the controller 305). The power from the power supply circuit 306 is supplied also to the head part 200 via the camera cable 400.

The camera cable 400 includes four cables 410 to 440. The cables 410 to 440 are used, for example, for transmitting a differential signal of data (image) (cables 410, 420), for power supply (cable 430), for GND (cable 440) and so on. Note that it is preferable to use a coaxial cable for the cable 410, 420 for transmitting the differential signal of data.

### (Details of Head Part 200)

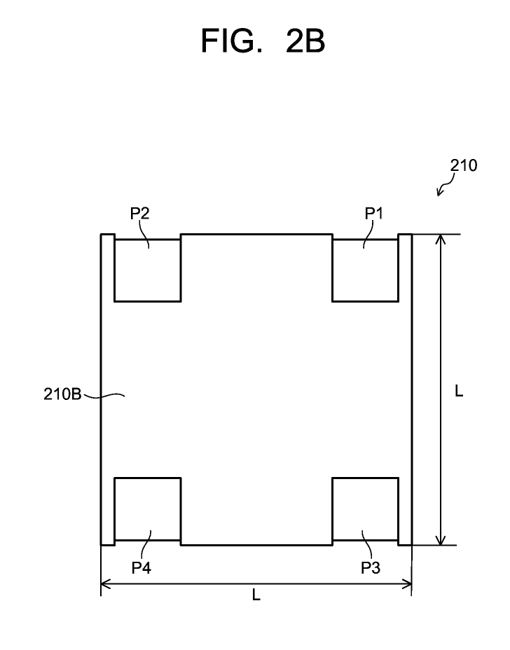

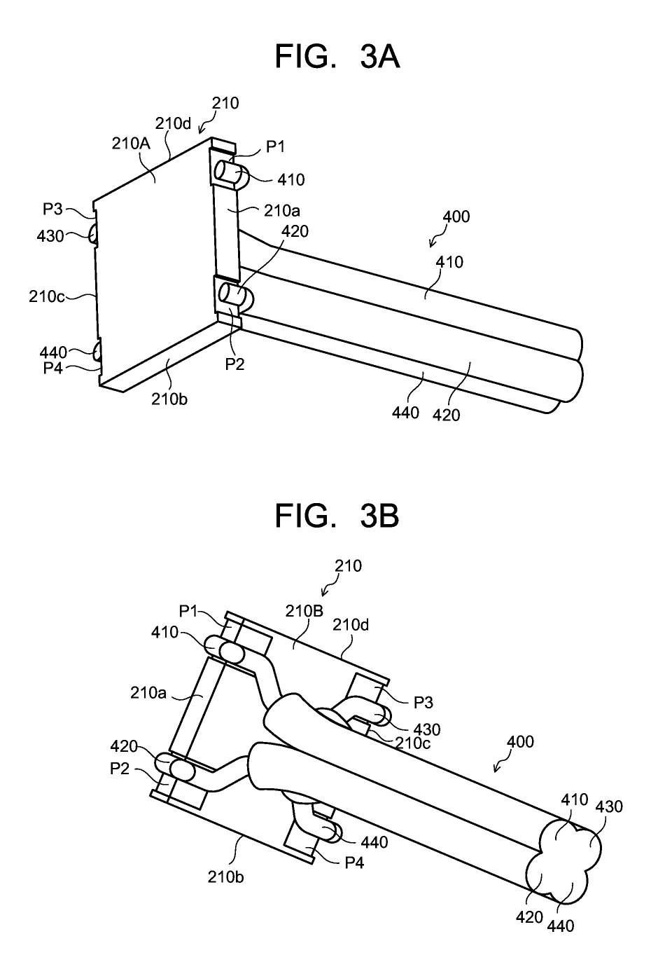

FIG. 2A and FIG. 2B are structural views of the image sensor 210. FIG. 2A is an overhead view of the image sensor 210 as seen from the rear surface side. FIG. 2B is a plan view of the image sensor 210 on the rear surface side. Further, FIG. 3A and FIG. 3B are structural views of the image sensor 210 with the camera cable 400 connected thereto. FIG. 3A is an overhead view of the image sensor 210 as seen from the front surface side. FIG. 3B is an overhead view of the image sensor 210 as seen from the rear surface side. Hereinafter, the structures of the image sensor 210 and the camera cable 400 will be described referring to FIG. 2A to FIG. 3B. Note that the illustration of the casing 220 of the head part 200 is omitted in FIG. 2A to FIG. 3B.

As illustrated in FIG. 2A to FIG. 3B, the image sensor 210 is rectangular. The image sensor 210 has a front surface 210A, a rear surface 210B and side surfaces 210a to 210d. On the side surface 210a of the image sensor 210, pads P1, P2 for connection with the camera cable 400 (hereinafter, referred to as connection pads P1, P2) are formed. On the side surface 210c of the image sensor 210 opposite the side surface 210a, pads P3, P4 for connection with the camera cable 400 (hereinafter, referred to as connection pads P3, P4) are further formed.

Note that the connection pads P1 to P4 can be formed by forming vias at the periphery of the image sensor 210 (at positions of the connection pads P1 to P4) and cutting (dicing) the image sensor 210 from a substrate (for example, a semiconductor wafer) such that side surfaces of the vias are exposed. Further, in the case where a plurality of connection pads are formed on one side surface as in this embodiment, it is preferable that the distance between the connection pads is large.

As illustrated in FIG. 2A to FIG. 3B, the connection pads P1 to P4 formed on the side surface 210a and the side surface 210c of the image sensor 210 extend down to the rear surface 210B of the image sensor 210. In addition, the image sensor 210 has a thickness d of 0.5 mm or less and a length L of each side of 1 mm or less.

On the front surface 210A of the image sensor 210, a plurality of imaging elements and peripheral circuits are further formed. Images captured by the plurality of imaging elements are transferred to the main body part 300 via the camera cable 400.

The cables 410 to 440 constituting the camera cable 400 are connected by soldering or the like on the connection pads P1 to P4 formed on the side surfaces 210a, 210c of the image sensor 210 respectively. As illustrated in FIG. 2A and FIG. 2B, the connection pads P1 to P4 extend down to the rear surface 210B of the image sensor 210. The cables 410 to 440 are connected to the connection pads P1 to P4 respectively also on the rear surface 210B of the image sensor 210.

### (Connecting Camera Cable 400 to Image Sensor 210)

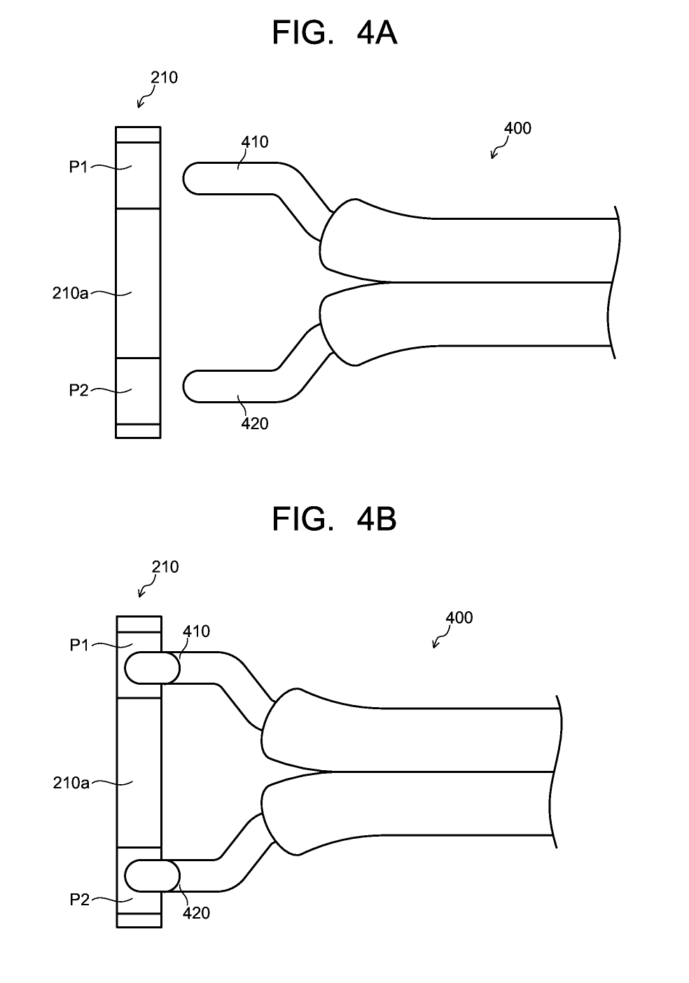

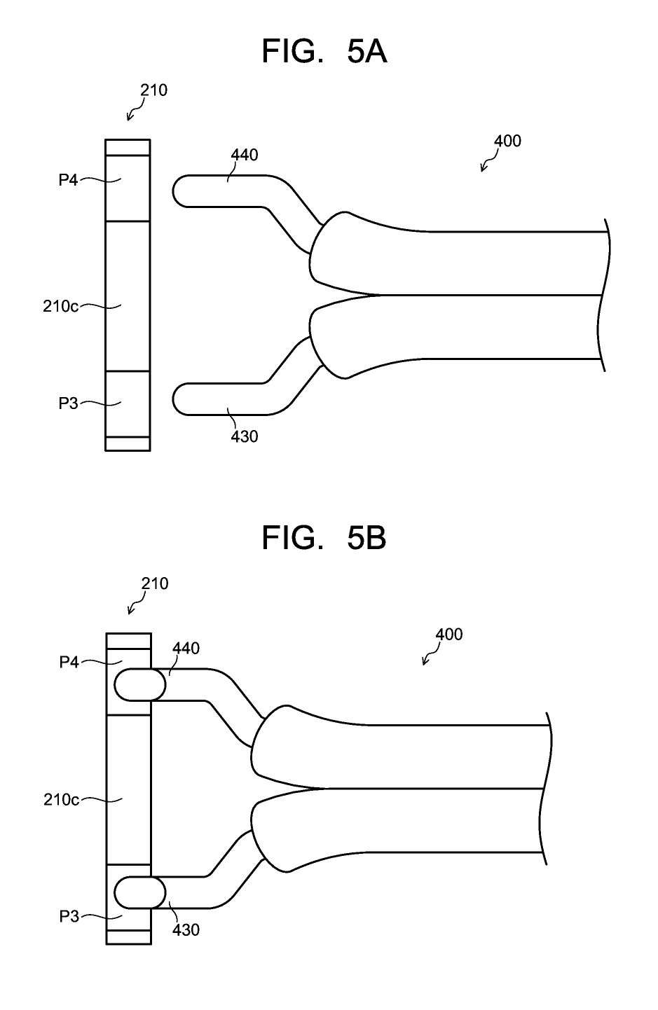

FIG. 4A to FIG. 5B are views illustrating a procedure of connecting the camera cable 400 to the image sensor 210. Hereinafter, the procedure (method) when connecting the camera cable 400 to the image sensor 210 will be described referring to FIG. 4A to FIG. 5B.

First, the image sensor 210 having the connection pads P1 to P4 extending down to the rear surface 210B formed on the side surface 210a and the side surface 210c, and the camera cable 400 are prepared. Note that it is preferable in terms of working efficiency to peel off the coating at tip end portions of the cables 410 to 440 of the camera cable 400 in advance to expose conducting wires therein.

Next, the image sensor 210 is fixed such that the side surface 210a having the connection pads P1, P2 formed thereon or the side surface 210c having the connection pads P3, P4 formed thereon can be seen (see FIG. 4A). Note that in FIG. 4A, the image sensor 210 is fixed with the side surface 210a having the connection pads P1, P2 formed thereon located on the upper side.

Next, the cables 410, 420 among the cables 410 to 440 of the camera cable 400 are connected to the connection pads P1, P2 respectively (see FIG. 4B). Note that as illustrated in FIG. 3B, the cables 410, 420 are preferably connected to portions where the connection pads P1, P2 extend down to the rear surface 210B of the image sensor 210.

Next, after the image sensor 210 is rotated so that the side surface 210c on the side to which the camera cable 400 is not connected can be seen, the image sensor 210 is fixed (see FIG. 5A). Then, the cables 430, 440 of the camera cable 400 are connected to the connection pads P3, P4 respectively (see FIG. 5B). Note that the cables 430, 440 are preferably connected to portions where the connection pads P3, P4 extend down to the rear surface 210B of the image sensor 210 as with the cables 410, 420. Note that it is preferable to use solder or a conductive paste for the connection of the cables 410 to 440 to the connection pads P1 to P4.

As described above, the connection pads P1 to P4 are formed not on the front surface 210A of the image sensor 210 but on the side surfaces 210a, 210c in this embodiment. Therefore, the image sensor 210 can be downsized. Further, the connection pads P1 to P4 are formed on the side surfaces 210a, 210c of the image sensor 210, so that when the camera cable 400 is connected to the connection pads P1 to P4, the cables 410 to 440 of the camera cable 400 can be connected from the side of the side surfaces of the image sensor 210, resulting in increased workability. This increases the workability when connecting the camera cable to the small image sensor 210, in particular, to an image sensor with a thickness d of 0.5 mm or less and a length L of each side of 1 mm or less.

Further, the connection pads P1 to P4 extend down to the rear surface 210B of the image sensor 210, and the cables 410 to 440 are also connected to the portions to which the connection pads P1 to P4 extend down to the rear surface 210B. This increases the connection reliability between the connection pads P1 to P4 and the cables 410 to 440 of the camera cable 400. As described above, in the cable connecting structure and the cable connecting method according to this embodiment, the image sensor can be downsized with the connection reliability of the cable ensured. Therefore, the cable connecting structure and the cable connecting method are preferable for the connection of the cable to an image sensor with a length of each side of 1 mm or less and a thickness of 0.5 mm or less.

### Modification Example 1 of Embodiment

The connecting of the camera cable 400 to the image sensor 210 having the connection pads P1, P2 formed on the side surface 210a and the connection pads P3, P4 formed on the side surface 210c as illustrated in FIG. 2A to FIG. 3B has been described in the above embodiment. An example in which each of the connection pads P1 to P4 is formed on each of the side surfaces of the image sensor will be described in a modification example 1 of the embodiment.

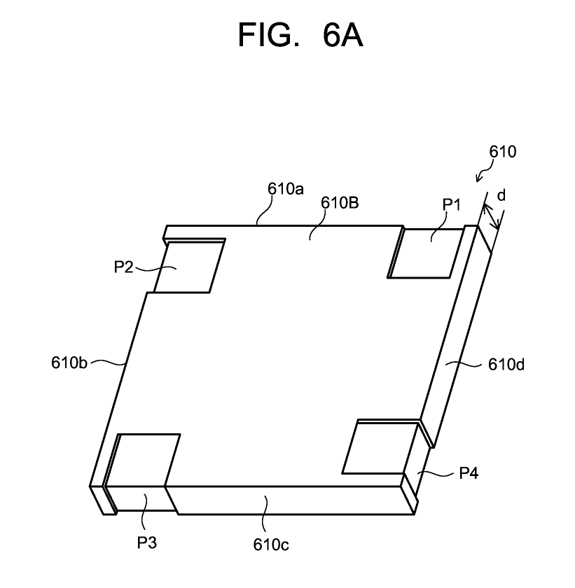

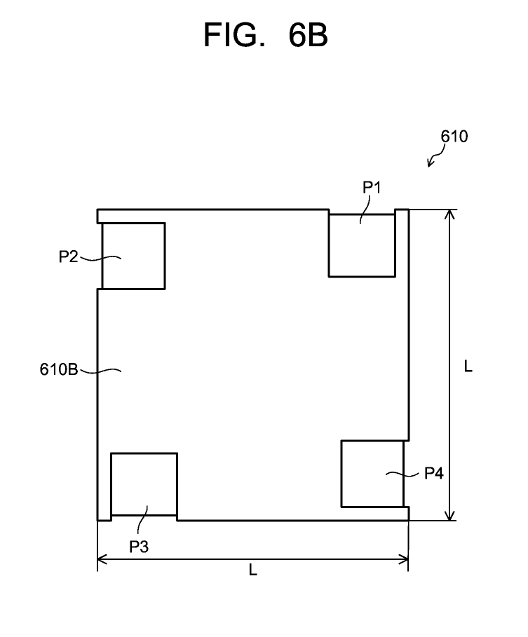

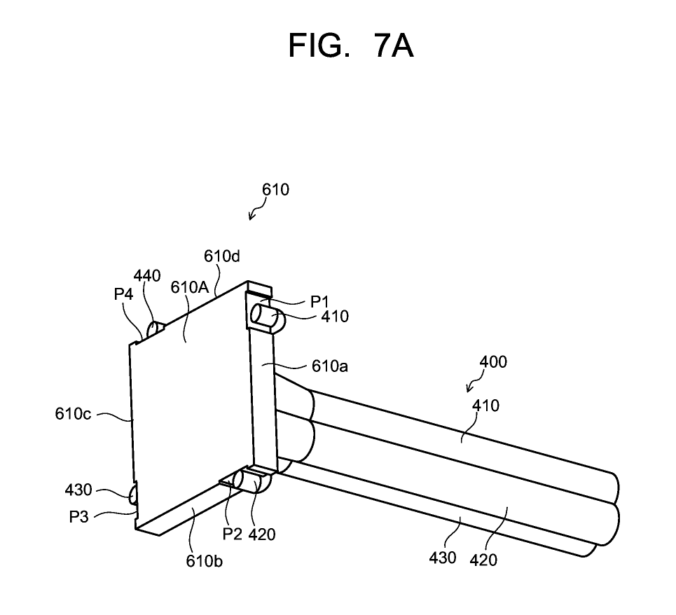

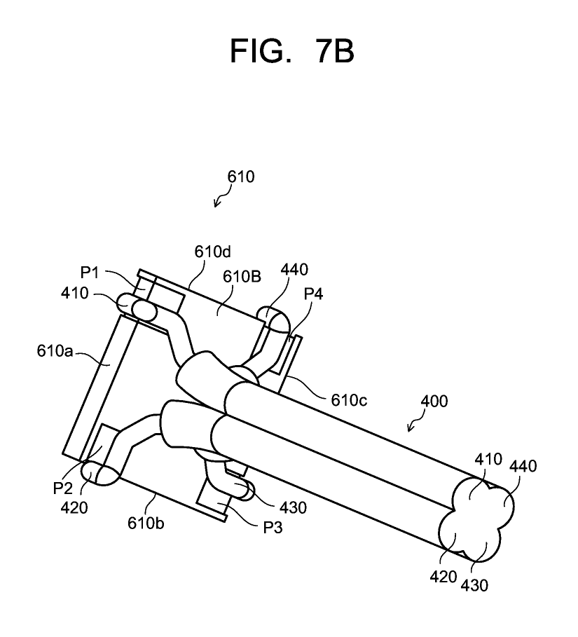

FIG. 6A and FIG. 6B are structural views of an image sensor 610 according to the modification example 1 of the embodiment. FIG. 6A is an overhead view of the image sensor 610 as seen from the rear surface side. FIG. 6B is a plan view of the image sensor 610 on the rear surface side. Further, FIG. 7A and FIG. 7B are structural views of the image sensor 610 with the camera cable 400 connected thereto. FIG. 7A is an overhead view of the image sensor 610 as seen from the front surface side. FIG. 7B is an overhead view of the image sensor 610 as seen from the rear surface side. Hereinafter, the configurations of the image sensor 610 and the camera cable 400 will be described referring to FIG. 6A to FIG. 7B. Note that the illustration of the casing 220 of the head part 200 is omitted in FIG. 6A to FIG. 7B.

As illustrated in FIG. 6A to FIG. 7B, the image sensor 610 is rectangular. The image sensor 610 has a front surface 610A, a rear surface 610B and side surfaces 610a to 610d. On the side surfaces 610a to 610d of the image sensor 610, pads P1 to P4 for connection with the camera cable 400 (hereinafter, referred to as connection pads P1 to P4) are formed respectively.

As illustrated in FIG. 6A to FIG. 7B, each of the connection pads P1 to P4 formed on each of the side surfaces 610a to 610d of the image sensor 610 extends down to the rear surface 610B of the image sensor 610. In addition, the image sensor 610 has a thickness d of 0.5 mm or less and a length L of each side of 1 mm or less.

On the front surface 610A of the image sensor 610, a plurality of imaging elements and peripheral circuits are further formed. Images captured by the plurality of imaging elements are transferred to the main body part 300 via the camera cable 400.

As described above, the connection pads P1 to P4 are formed on the side surfaces 610a to 610d of the image sensor 610 respectively in the modification example 1 of the embodiment. Therefore, the distances between the connection pads P1 to P4 are increased, further increasing the workability when connecting the camera cable 400 to the connection pads P1 to P4. The other effects are the same as those of the cable connecting structure and the cable connecting method according to the embodiment.

### Modification Example 2 of Embodiment

Though each of the connection pads P1 to P4 is formed at an eccentric position on each of the side surfaces 610a to 610d of the image sensor 610 as illustrated in FIG. 6A to FIG. 7B has been described in the modification example 1 of the embodiment, an example in which each of the connection pads P1 to P4 is formed at substantially the center of each of the side surfaces of the image sensor will be described in a modification example 2 of the embodiment.

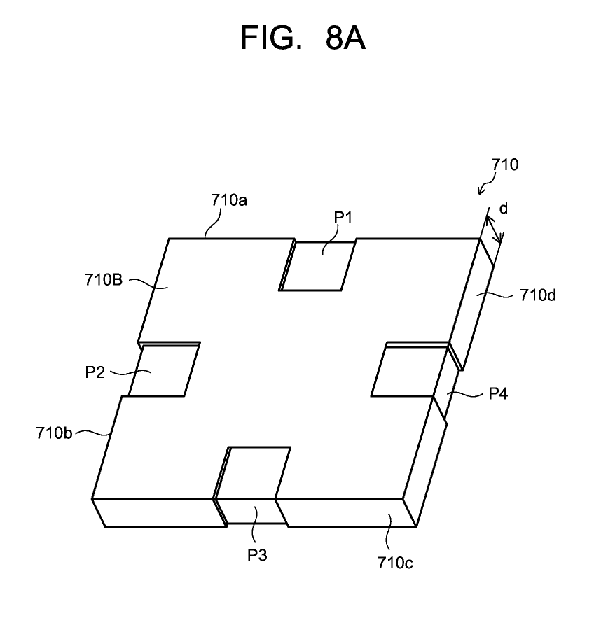

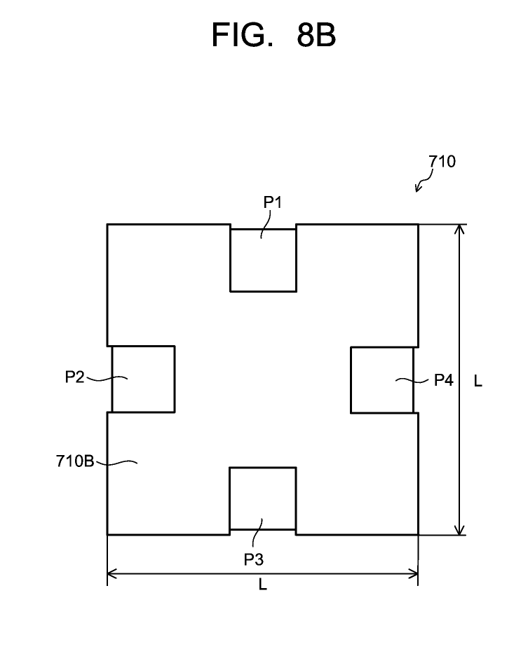

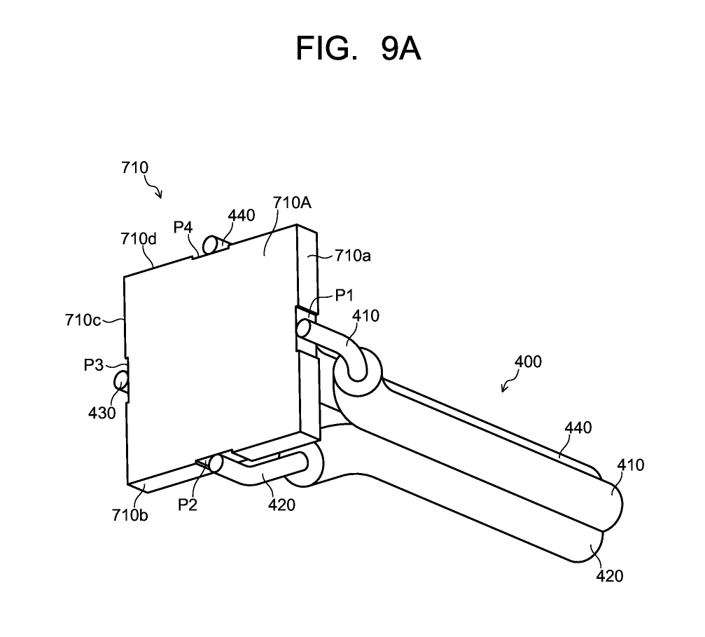

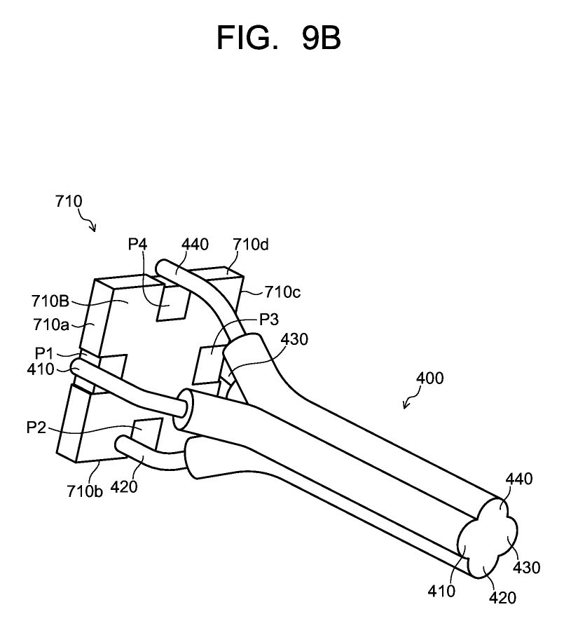

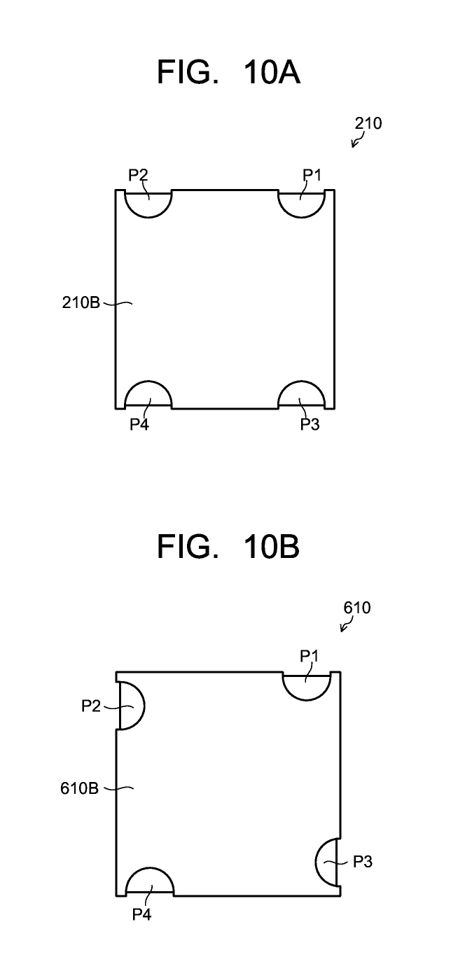

FIG. 8A and FIG. 8B are structural views of an image sensor 710 according to the modification example 2 of the embodiment. FIG. 8A is an overhead view of the image sensor 710 as seen from the rear surface side. FIG. 8B is a plan view of the image sensor 710 on the rear surface side. Further, FIG. 9A and FIG. 9B are structural views of the image sensor 710 with the camera cable 400 connected thereto. FIG. 9A is an overhead view of the image sensor 710 as seen from the front surface side. FIG. 9B is an overhead view of the image sensor 710 as seen from the rear surface side. Hereinafter, the configurations of the image sensor 710 and the camera cable 400 will be described referring to FIG. 8A to FIG. 9B. Note that the illustration of the casing 220 of the head part 200 is omitted in FIG. 8A to FIG. 9B.

As illustrated in FIG. 8A to FIG. 9B, the image sensor 710 is rectangular. The image sensor 710 has a front surface 710A, a rear surface 710B and side surfaces 710a to 710d. At substantially the centers of the side surfaces 710a to 710d of the image sensor 710, pads P1 to P4 for connection with the camera cable 400 (hereinafter, referred to as connection pads P1 to P4) are formed respectively.

As illustrated in FIG. 8A to FIG. 9B, each of the connection pads P1 to P4 formed on each of the side surface 710a to 710d of the image sensor 710 extends down to the rear surface 710B of the image sensor 710. In addition, the image sensor 710 has a thickness d of 0.5 mm or less and a length L of each side of 1 mm or less.

On the front surface 710A of the image sensor 710, a plurality of imaging elements and peripheral circuits are further formed. Images captured by the plurality of imaging elements are transferred to the main body part 300 via the camera cable 400.

As described above, the connection pads P1 to P4 are formed at substantially the centers of the side surfaces 710a to 710d of the image sensor 710 respectively in the modification example 2 of the embodiment. The effects are the same as those of the cable connecting structure and the cable connecting method according to the modification example 1 of the embodiment

### Other Embodiments

While certain embodiments have been described, these embodiments have been presented by way of example only, and are not intended to limit the scope of the inventions. Indeed, the novel embodiment described herein may be embodiment in a variety of other forms; furthermore, substitutions and changes in the form of the embodiments described herein may be made without departing from the spirit of the inventions. The accompanying claims and their equivalents are intended to cover such forms or modifications as would fall within the scope and spirit of the inventions.

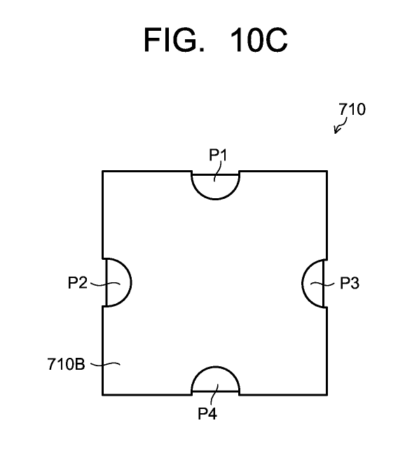

For example, the shape of the connection pads P1 to P4 of the image sensors 210, 610, 710 described referring to FIG. 2A and FIG. 2B, FIG. 6A and FIG. 6B, FIG. 8A and FIG. 8B is rectangular in a top view but may be semicircular as illustrated in FIG. 10A, FIG. 10B, FIG. 10C. Further, the number of cables connected to the image sensor is not limited to four.

What is claimed is:

1. A cable connecting structure, comprising:
a semiconductor chip configured to have a plurality of imaging elements on a front surface thereof and a connection pad formed on a side surface thereof; and
a cable configured to be connected to the connection pad.

2. The structure of claim 1,
wherein the connection pad is configured to extend down to a rear surface of the semiconductor chip; and
wherein the cable is configured to be connected to the connection pad also on the rear surface of the semiconductor chip.

3. The structure of claim 1,
wherein the semiconductor chip is configured to be a rectangle having first to fourth side surfaces; and
wherein the connection pad is configured to be formed on each of the first to fourth side surfaces.

4. The structure of claim 1,
wherein the semiconductor chip is configured to be a rectangle having first to fourth side surfaces; and
wherein the connection pad is configured to be formed on each of the first side surface and the second side surface opposite the first side surface.

5. The structure of claim 1,
wherein the semiconductor chip is configured to have a length of each side of 1 mm or less.

6. The structure of claim 1,
wherein the semiconductor chip is configured to have a thickness of 0.5 mm or less.

7. A cable connecting method of connecting a cable to a connection pad, from a side of a semiconductor chip configured to have a plurality of imaging elements on a front surface thereof and configured to have the connection pad formed on a side surface thereof.

8. The method of claim 7,
wherein the connection pad is configured to extend down to a rear surface of the semiconductor chip; and
wherein the cable is configured to be connected to the connection pad extending down to the rear surface of the semiconductor chip.

9. The method of claim 7,
wherein the semiconductor chip is configured to be a rectangle having first to fourth side surfaces; and
wherein the cable is configured to be connected to the connection pad formed on each of the first to fourth side surfaces.

10. The method of claim 7,
wherein the semiconductor chip is configured to be a rectangle having first to fourth side surfaces; and
wherein the cable is configured to be connected to the connection pad formed on each of the first side surface and the second side surface opposite the first side surface.

11. The method of claim 7,
wherein the semiconductor chip is configured to have a length of each side of 1 mm or less.

12. The method of claim 7,
wherein the semiconductor chip is configured to have a thickness of 0.5 mm or less.
